(19) United States
(12) Patent Application Publication
(10) Pub. No.: US 2025/0349377 A1
(43) Pub. Date: Nov. 13, 2025

(54) ARRAY OF MULTI-VALUE NON-VOLATILE MEMORY CELLS

(71) Applicant: Silicon Storage Technology, Inc., San Jose, CA (US)

(72) Inventors: Hieu Van Tran, San Jose, CA (US); Jeng-Wei Yang, Zhubei City (TW); Man-Tang Wu, Hsinchu Cty. (TW); Nhan Do, Saratoga, CA (US)

(21) Appl. No.: 18/782,022

(22) Filed: Jul. 23, 2024

Related U.S. Application Data
(60) Provisional application No. 63/645,783, filed on May 10, 2024.

(51) Int. Cl. G11C 27/00

(52) U.S. Cl. CPC G11C 27/005

(57) ABSTRACT

In one example, a system comprises an array of non-volatile memory cells arranged into rows and columns, each non-volatile memory cell comprising a first bit line terminal, a first erase gate terminal, a first control gate terminal, a first floating gate, a word line, a second floating gate, a second control gate terminal, a second erase gate terminal, and a second bit line terminal, wherein the first floating gate can store a first digital or analog value and the second floating gate can store a second digital or analog value; and a bit line decoder for a column to selectively provide a first voltage to the first bit line terminals of non-volatile memory cells in the column and a second voltage to the second bit line terminals of the non-volatile memory cells in the column.

### PRIORITY CLAIM

This application claims priority to U.S. Provisional Patent Application No. 63/645,783, filed on May 10, 2024, and titled, “Array of Multi-Value Non-Volatile Memory Cells,” which is incorporated by reference herein.

### FIELD OF THE INVENTION

Numerous examples are disclosed of an array of multi-value non-volatile memory cells and associated decoders.

### BACKGROUND OF THE INVENTION

FIG. 1 illustrates memory cell 100, which is a multi-value non-volatile memory cell. Specifically, memory cell 100 can store different values in two different floating gates. Each value can be a binary value (e.g., 0 or 1) or an analog value (e.g., a value within a range of possible values not limited to 0 or 1).

Memory cell 100 comprises floating gate (FGB) 12 disposed over and insulated from substrate 10 and control gate terminal (CGB) 14 disposed over and insulated from floating gate (FGB) 12. To one side of floating gate (FGB) 12 and control gate terminal (CGB) 14 is word line terminal (WL) 30, and to the other side of floating gate (FGB) 12 and control gate terminal (CGB) 14 is erase gate terminal (EGB) 16. Bit line terminal (BLB) 18 is disposed in the substrate 10 underneath erase gate terminal (EGB) 16. Memory cell 100 further comprises floating gate (FGT) 22 disposed over and insulated from substrate 10 and control gate terminal (CGT) 24 disposed over and insulated from floating gate (FGT) 22. To one side of floating gate (FGT) 22 and control gate terminal (CGT) 24 is word line terminal (WL) 30, and to the other side of floating gate (FGT) 22 and control gate terminal (CGT) 24 is erase gate terminal (EGT) 26. Bit line terminal (BLT) 28 is disposed in the substrate 10 underneath erase gate terminal (EGT) 26. Floating gate (FGB) 12 and floating gate (FGT) 22 each can store values. A single continuous channel region 22 extends from bit line terminal (BLB) 18 to bit line terminal (BLT) 28. In the abbreviations used above, “T” stands for top and “B” stands for bottom as a way to differentiate between the two portions of memory cell 100 that can each store a value. The top and bottom labels refer to the relative placement of the two portions when viewed in a logical circuit layout such as in FIG. 2. Those portions also can be referred to as separate memory cells.

FIG. 2 depicts a logical circuit layout for memory cell 100. Memory cell 100 comprises bit line terminal (BLT) 28, erase gate terminal (EGT) 26, control gate terminal (CGT) 24, floating gate (FGT) 22, word line terminal (WL) 30, floating gate (FGB) 12, control gate terminal (CGB) 14, erase gate terminal (EGB) 16, and bit line terminal (BLB) 18.

The design of memory cell 100 poses a challenge for assembling an array of such memory cells in a way where each portion of each memory cell 100 can be programmed, erased, and read in an efficient manner. What is needed are improved array designs and decoders used in conjunction with memory cells based on the design of memory cell 100.

### BRIEF SUMMARY OF THE INVENTION

Numerous examples are disclosed of an array of multi-value non-volatile memory cells and associated decoders.

### BRIEF DESCRIPTION OF THE DRAWINGS

FIG. 1 is a cross section of a memory cell.

FIG. 2 is a logical depiction of the memory cell of FIG. 1.

FIG. 3 depicts a memory array.

FIG. 4 depicts voltages to apply to various terminals of memory cells in an array to perform erase, read, and program operations.

FIG. 5 depicts voltages to apply to various terminals of memory cells in an array to perform erase, read, and program operations.

FIG. 6 depicts voltages to apply to various terminals of memory cells in an array to perform erase, read, and program operations.

FIG. 7 depicts voltages to apply to various terminals of memory cells in an array to perform erase, read, and program operations.

FIG. 8 depicts a bit line decoder.

FIG. 9 depicts a bit line decoder.

FIG. 10 depicts a row decoder.

FIG. 11 depicts an erase gate decoder.

FIG. 12 depicts an erase gate decoder.

FIG. 13 depicts a control gate decoder.

FIG. 14 depicts a word line decoder.

FIG. 15 depicts a memory array.

FIG. 16 depicts a memory array.

FIG. 17 depicts a memory array.

FIG. 18 depicts a memory array.

FIG. 19 depicts a memory array.

FIG. 20 depicts a memory array.

FIG. 21 depicts a memory array.

FIG. 22 depicts a memory array.

FIG. 23 depicts a memory array.

FIG. 24 depicts a memory array.

FIG. 25 depicts a memory array.

FIG. 26 depicts a memory array.

FIG. 27 depicts a memory array.

FIG. 28 depicts a memory array.

FIG. 29 depicts a memory array.

### DETAILED DESCRIPTION OF THE INVENTION

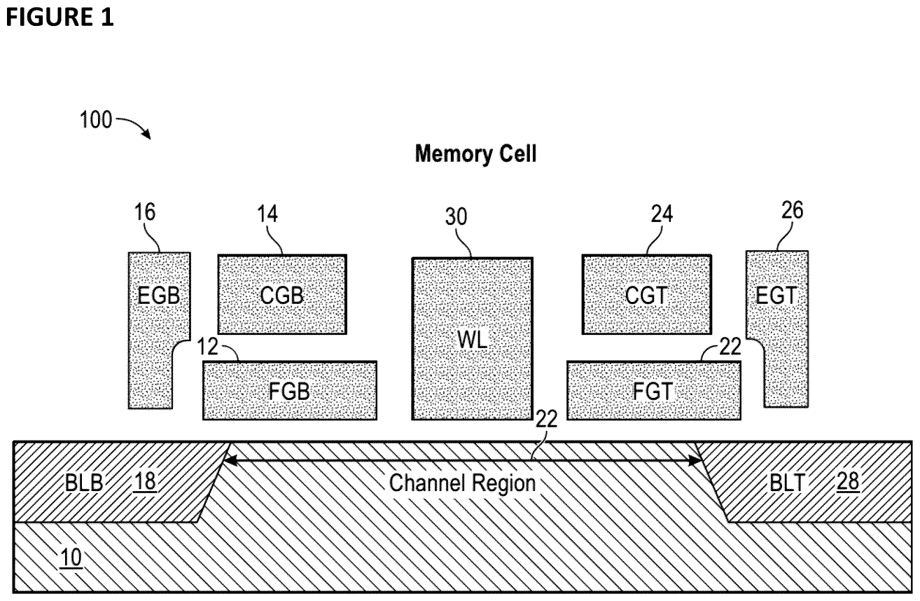

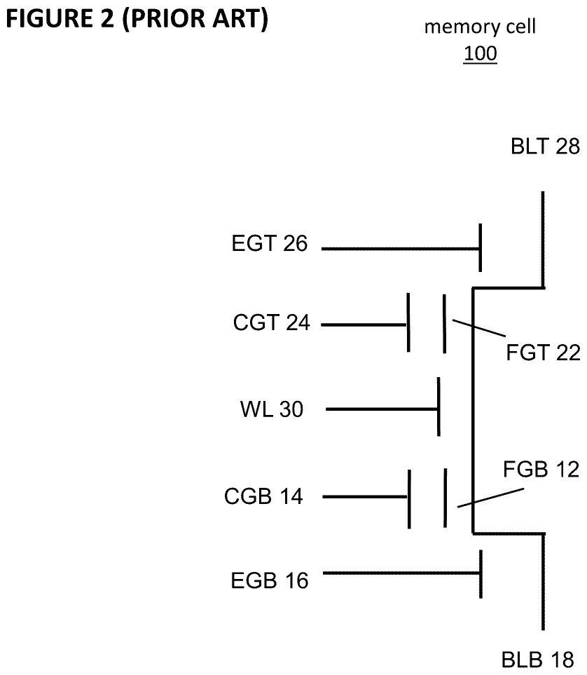

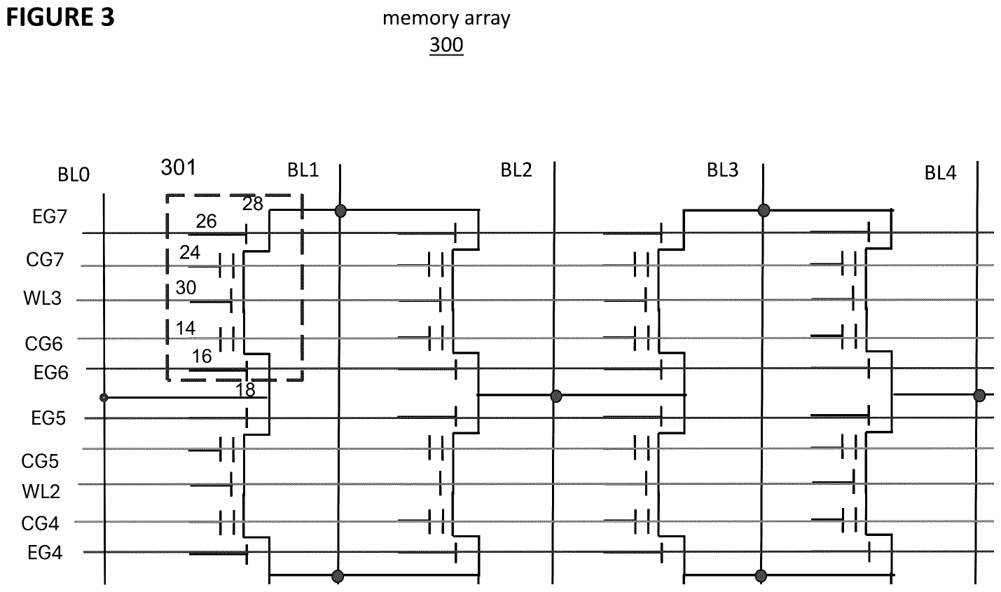

FIG. 3 depicts memory array 300 (1BL1COL, one bitine per one column of memory cells). Memory array 300 comprises an array of memory cells based on the design of memory cell 100 in FIGS. 1 and 2, where the memory cells are arranged into rows and columns. Memory cell 301 is an example of a memory cell 100 in memory array 300. Erase gate lines EG7 and EG6 connect to erase gate terminals (EGT) 26 and (EGB) 16, respectively, of memory cell 301, control gate lines CG7 and CG6 connect to control gate terminals (CGT) 24 and (CGB) 14, respectively, of memory cell 301, bit lines BL1 and BL0 connect to bit line terminals (BLT) 28 and (BLB) 18, respectively, of memory cell 301, and word line WL3 connects to word line terminal (WL) 30 of memory cell 301. The other memory cells in memory array 300 follow the same design as memory cell 301.

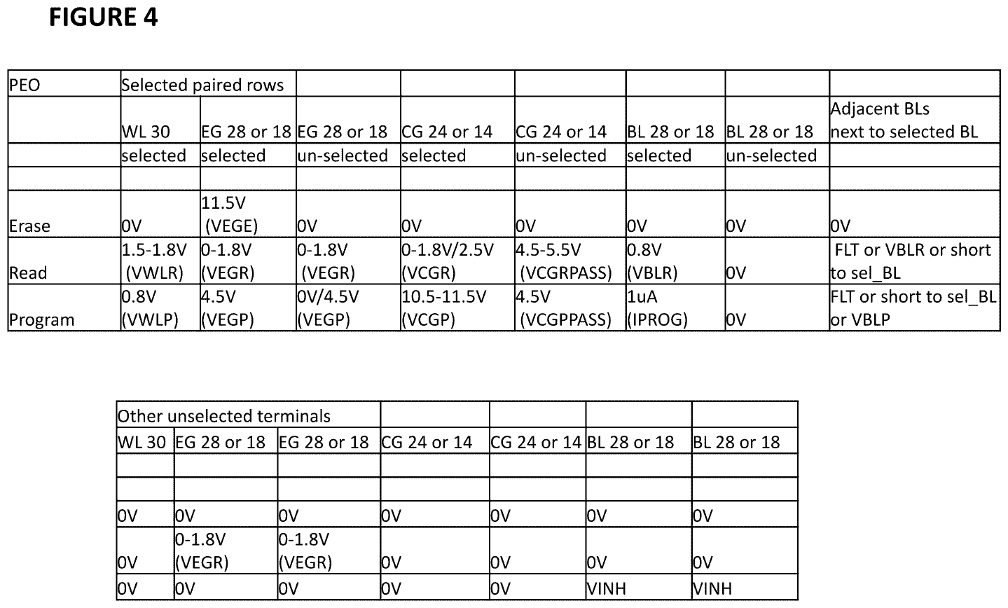

FIG. 4 depicts a first set of example voltages for 1BL1COL array to apply to bit line terminal (BLT) 28, erase gate terminal (EGT) 26, control gate terminal (CGT) 24, word line terminal (WL) 30, control gate terminal (CGB) 14, erase gate terminal (EGB) 16, and bit line terminal (BLB) 18 for a selected portion of memory cell 100 and an unselected portion of memory cell 100 to perform erase, read, and program operations on the selected portion of memory cell 100. Memory cell 301 in FIG. 3 is an example of memory cell 100. Adjacent bitlines to the selected bitlines are either floating, shorted to selected bitlines, or receive the same voltage applied to the selected bitlines in read or programming.

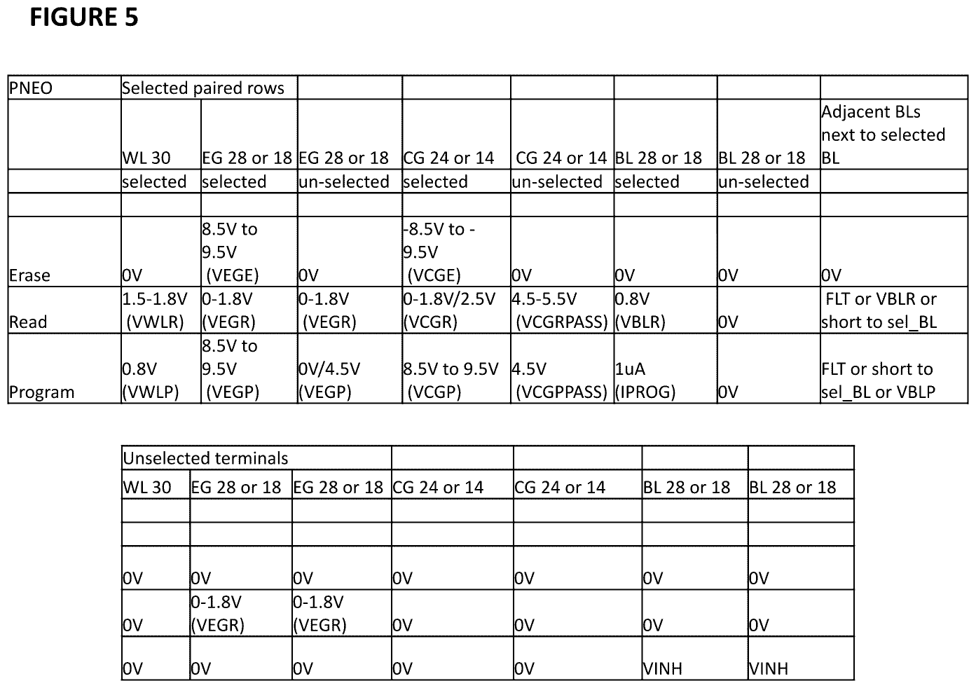

FIG. 5 depicts a second set of example voltages for a 1BL1COL array with negative CG in erase to apply to bit line terminal (BLT) 28, erase gate terminal (EGT) 26, control gate terminal (CGT) 24, word line terminal (WL) 30, control gate terminal (CGB) 14, erase gate terminal (EGB) 16, and bit line terminal (BLB) 18 for a selected portion of memory cell 100 and an unselected portion of memory cell 100 to perform erase, read, and program operations on the selected portion of memory cell 100. Adjacent bitlines to the selected bitlines are either floating, shorted to selected bitlines, or receive the same voltage applied to the selected bitlines in read or programming.

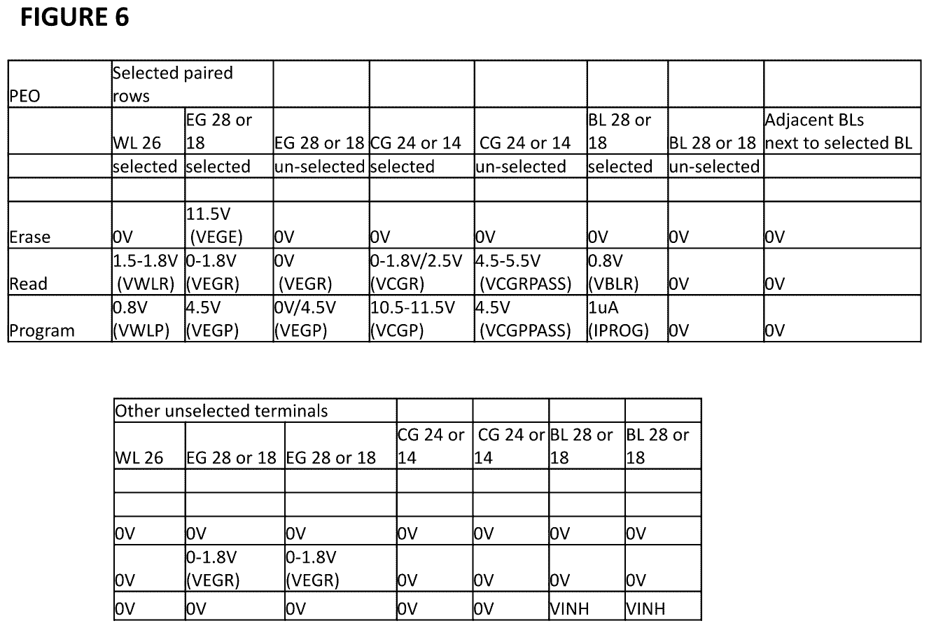

FIG. 6 depicts a third set of example voltages for a 2BL1COL array to apply to bit line terminal (BLT) 28, erase gate terminal (EGT) 26, control gate terminal (CGT) 24, word line terminal (WL) 30, control gate terminal (CGB) 14, erase gate terminal (EGB) 16, and bit line terminal (BLB) 18 for a selected portion of memory cell 100 and an unselected portion of memory cell 100 to perform erase, read, and program operations on the selected portion of memory cell 100.

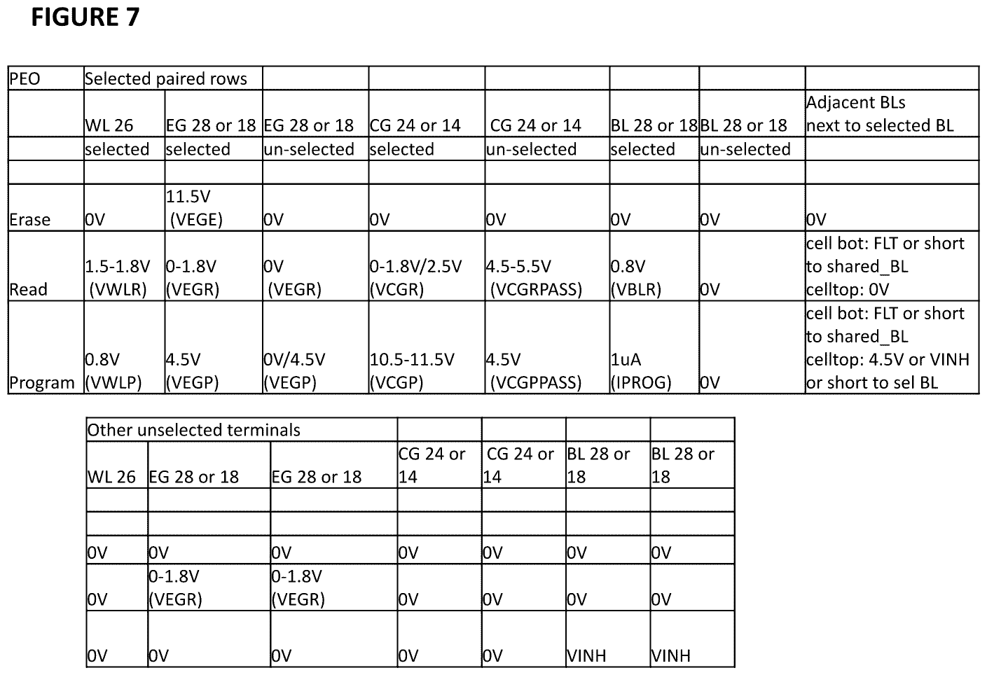

FIG. 7 depicts a fourth set of example voltages for a 1.5BL1COL array to apply to bit line terminal (BLT) 28, erase gate terminal (EGT) 26, control gate terminal (CGT) 24, word line terminal (WL) 30, control gate terminal (CGB) 14, erase gate terminal (EGB) 16, and bit line terminal (BLB) 18 for a selected portion of memory cell 100 and an unselected portion of memory cell 100 to perform erase, read, and program operations on the selected portion of memory cell 100.

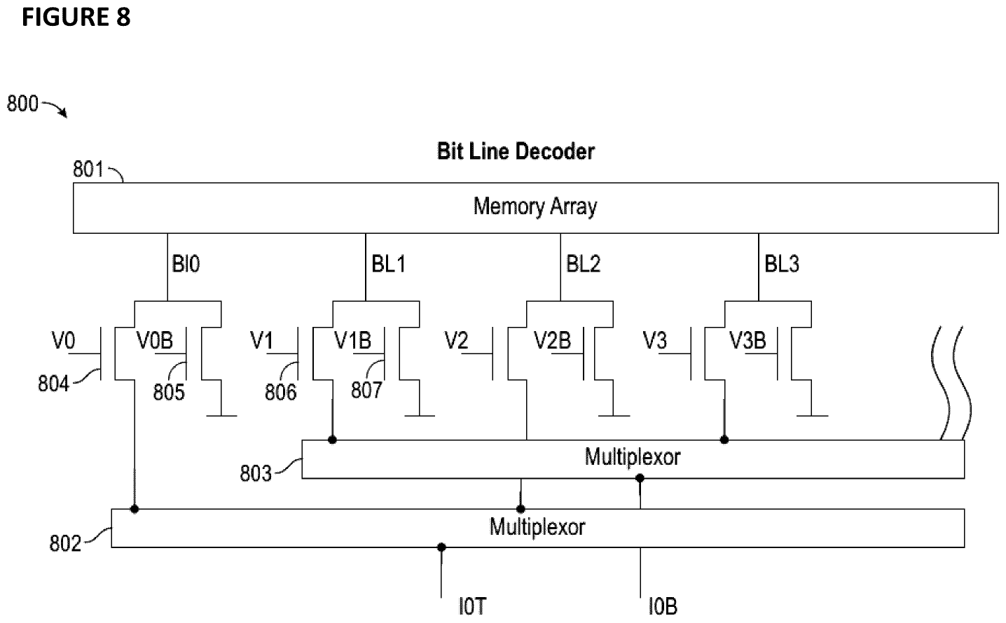

FIG. 8 depicts bit line decoder 800. Bit line decoder 800 is connected to bit lines of memory array 801. The BLT bit lines in memory array 801 are selectively coupled to signal IOT by multiplexor 802. The BLB bit lines in memory array 801 are selectively coupled to signal IOB by multiplexor 803. For example, bit line BL0 (which is a BLT 28) is coupled to multiplexor 802 through transistor 804. When multiplexor 802 selects bit line BL0 and V0 is asserted, bit line BL0 receives signal IOT through transistor 804. When multiplexor 802 selects bit line BL0 and V0 is not asserted, V0B will be asserted and bit line BL0 is coupled to a bias (e.g. ground or a voltage) through transistor 805 or will float. Similarly, bit line BL1 (which is a BLB 18) is coupled to multiplexor 803 through transistor 808. When multiplexor 803 selects bit line BL1 and V1 is asserted, bit line BL1 receives signal IOB through transistor 806. When multiplexor 803 selects bit line BL1 and V1 is not asserted, V1B will be asserted and bit line BL1 is coupled to a bias (e.g. ground or a voltage) through transistor 807 or will float. In this example, BL0 and BL1 will connect to a column of cells based on the design of memory cell 100. The BLT 28 terminals of cells in the column will connect to BL0, and the BLB 18 terminals of cells in the column will connect to BL1.

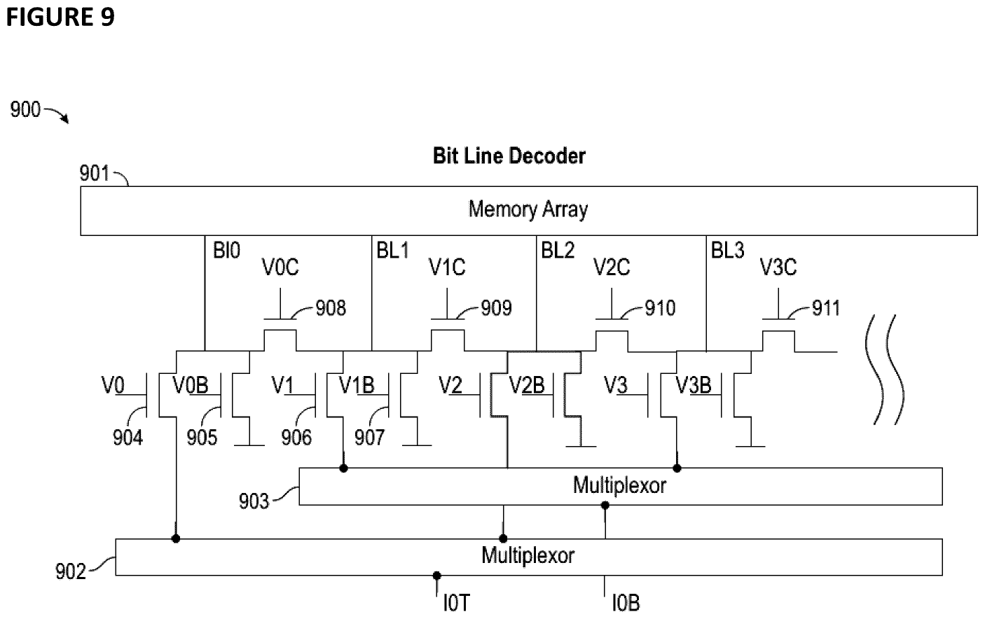

FIG. 9 depicts bit line decoder 900. Bit line decoder 900 is connected to bit lines of memory array 901. The BLT bit lines in memory array 901 are selectively coupled to signal IOT by multiplexor 902. The BLB bit lines in memory array 901 are selectively coupled to signal IOB by multiplexor 903. For example, bit line BL0 (which is a BLT 28) is coupled to multiplexor 902 through transistor 904. When multiplexor 902 selects bit line BL0 and V0 is asserted, bit line BL0 receives signal IOT through transistor 904. When multiplexor 902 selects bit line BL0 and V0 is not asserted, V0B will be asserted and bit line BL0 is coupled to a bias (e.g. ground or a voltage) through transistor 905 or will float. Similarly, bit line BL1 (which is a BLB 18) is coupled to multiplexor 903. When multiplexor 903 selects bit line BL1 and V1 is asserted, bit line BL1 receives signal IOB through transistor 906. When multiplexor 903 selects bit line BL1 and V1 is not asserted, V1B will be asserted and bit line BL1 is coupled to a bias (e.g. ground or a voltage) through transistor 907 or will float. Transistor 908 connects (shorts) BL0 and BL1 when V0C is asserted, which can occur when it is desired for BL0 and BL1 to be at the same voltage (such as both at a bias voltage level). Transistors 909, 910, 911, and others not shown similarly short adjacent bitlines when their gates are turned on.

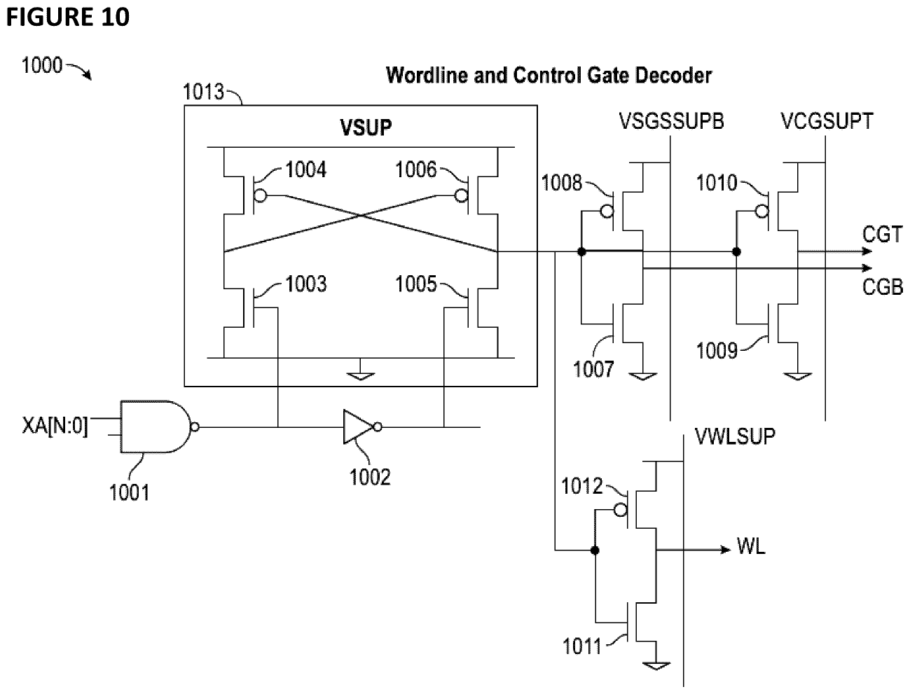

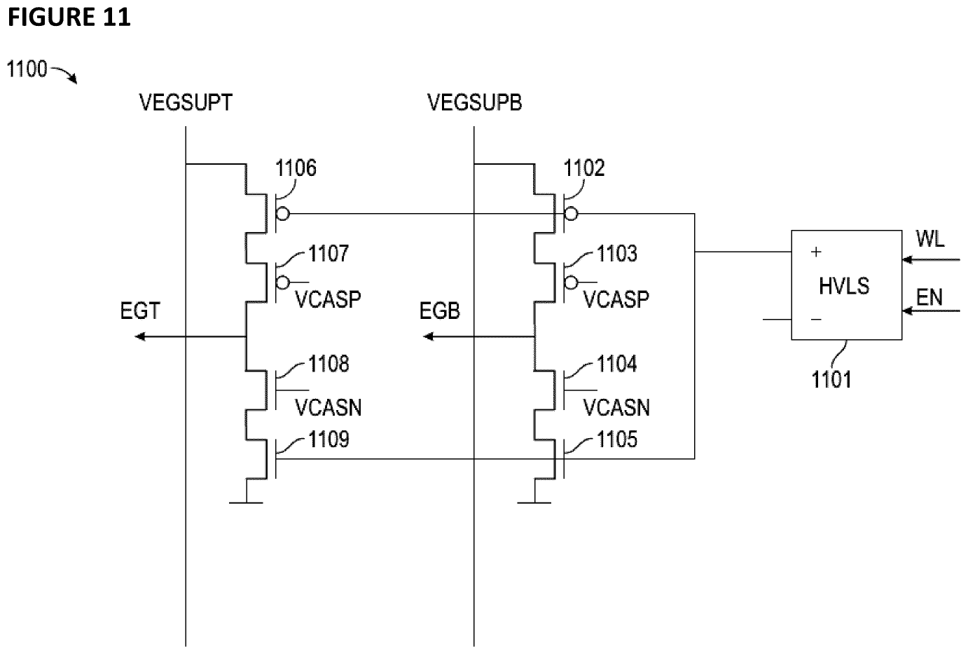

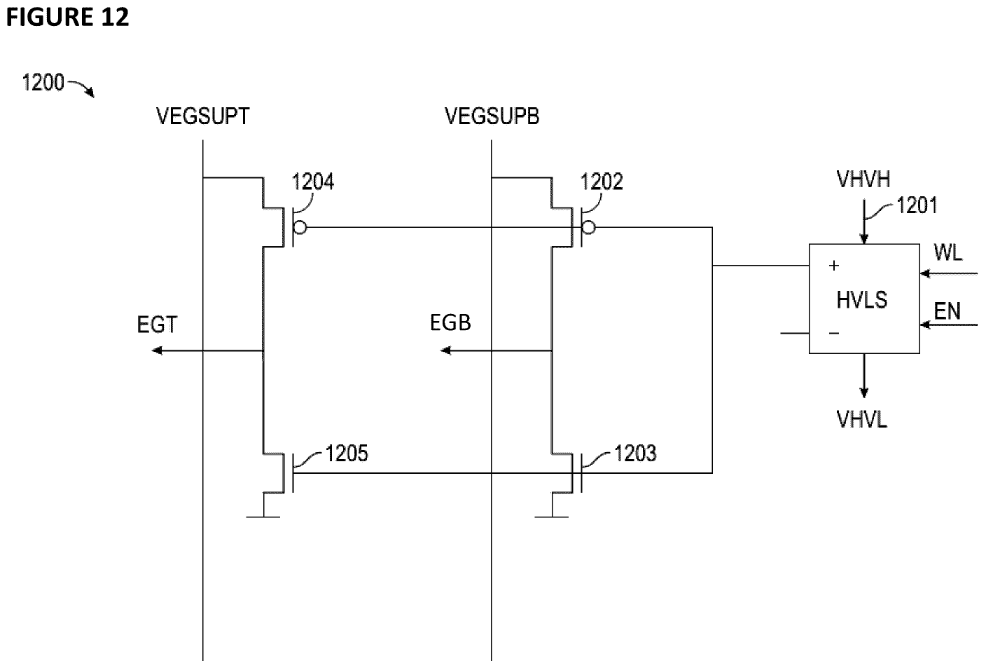

FIGS. 10, 11, and 12 depict portions of a row decoder, where the row decoder provides word line, control gate line, and erase gate line signals for a particular row. The same circuitry will be present for all other rows in a memory array. FIGS. 11 and 12 depict alternative examples of erase gate decoder circuitry.

FIG. 10 depicts a portion of wordline and control gate decoder 1000 associated with a single row in a memory array. It is to be understood that the same circuitry will be contained for all other rows in the memory array. A decoded row address, XA[N:0] comprising N+1 lines, is received by NAND gate 1001. When the decoded row address corresponds to the row in question, the output of NAND gate will be 0 (meaning that the row is being selected); in all other instances, it will be 1 (meaning that the row is unselected). Inverter 1002 receives the output of NAND gate 1001 and inverts the signal, such that the output of inverter is 1 when the row is being selected and 0 when the row is unselected.

When the input to inverter 1002 is 0 and the output of inverter is 1 (meaning that the row is being selected), NMOS transistor 1003 is turned off, NMOS transistor 1005 is turned on, the gate of PMOS transistor 1004 is pulled to ground by NMOS transistor 1005 and PMOS transistor 1004 is turned on, which pulls the gate of PMOS transistor 1006 high and turns off PMOS transistor 1006, and the output of level shifter 1013 will be at ground. Because the output of level shifter 1013 is at ground, PMOS transistors 1008, 1010, and 1012 will turn on, pulling CGT, CGB, and WL high to VCGSUPB, VCGSUPT, and VWLSUP, respectively, and NMOS transistors 1007, 1008, and 1011 will be off. WL is applied to word line terminals of the cells in the row, CGT is applied to control gate terminals (CGT) 24 of the cells in the row, and CGB is applied to control gate terminals (CGB) 14 of the cells in the row.

When the input to inverter 1002 is 1 and the output of inverter is 0 (meaning that the row is unselected), NMOS transistor 1003 is turned on, NMOS transistor 1005 is turned off, the gate of PMOS transistor 1006 is pulled to ground by NMOS transistor 1003 and PMOS transistor 1006 is turned on, which pulls the gate of PMOS transistor 1004 high and turns off PMOS transistor 1004, and the output of level shifter 1013 will be high at VSUP. Because the output of level shifter 1013 is high, PMOS transistors 1008, 1010, and 1012 will turn off and NMOS transistors 1007, 1009, and 1011 will turn on, pulling CGT, CGB, and WL to ground. WL is applied to word line terminals of the cells in the row, CGT is applied to control gate terminals (CGT) 24 of the cells in the row, and CGB is applied to control gate terminals (CGB) 14 of the cells in the row.

Supply voltages VWLSUP, VCGSUPB, and VCGSUPT are supplied to terminals WL, CGB, and CGT, respectively. These are supplied per the table in FIGS. 4, 5, 6, and 7 for xBLyCOL (i.e., 1BL1COL, 2BL1COL, 1.5BL1COL) array architectures.

FIG. 11 depicts a portion of erase gate decoder 1100 associated with a single row in a memory array. It is to be understood that the same circuitry will be contained for all other rows in the memory array. Erase gate decoder 1100 receives the word line signal, WL, generated by wordline and control gate decoder 1000 in FIG. 10, as well as an enable signal, EN. Erase gate decoder 1100 comprises high voltage level shifter 1101, PMOS transistors 1102, 1103, 1106, and 1107, and NMOS transistors 1104, 1105, 1108, and 1109. Transistors 1103, 1104, 1107, and 1108 serve as cascoding transistors, meaning they reduce the voltage stress of the select transistors in series, namely, transistors 1102, 1105, 1106, and 1109 transistors when in an off condition. WL is high when the relevant row is selected. EN is asserted when it is desired to apply a non-zero voltage to erase gate terminals of the row. High voltage level shifter 1101 receives the high WL signal and transforms it into a voltage signal of a different voltage, usually a higher voltage. The high voltage is applied to the gates of select PMOS transistors 1102 and 1106 and select NMOS transistors 1005 and 1009. When the output of high voltage level shifter 1101 is low, EGT and EGB will be pulled up to VEGSUPT and VEGSUPB, respectively. When the output of high voltage level shifter 1101 is high, EGT and EGB will be pulled to a bias level (e.g., a low voltage or ground). EGT is applied to erase gate terminals (EGT) 26 of the cells in the row, and EGB is applied to erase gate terminals (EGB) 16 of the cells in the row. The voltages are supplied per one of the tables in FIGS. 4, 5, 6, and 7.

FIG. 12 depicts a portion of erase gate decoder 1200 associated with a single row in a memory array. It is to be understood that the same circuitry will be contained for all other rows in the memory array. Erase gate decoder 1200 receives the word line signal, WL, generated by wordline and control gate decoder 1000 in FIG. 10, as well as an enable signal, EN. Erase gate decoder 1200 is similar to erase gate decoder 1100 in FIG. 11 but does not have the cascoding transistors. Erase gate decoder 1200 comprises high voltage level shifter 1201, PMOS transistors 1202 and 1204 and NMOS transistors 1203 and 1205. WL is high when the relevant row is selected. EN is asserted when it is desired to apply a non-zero voltage erase gate terminals of the row. High voltage level shifter 1201 receives the high WL signal and transforms it into a voltage signal of a different voltage, usually a higher voltage. The high voltage is applied to the gates of PMOS transistors 1202 and 1204 and NMOS transistors 1203 and 1205. When the output of high voltage level shifter 1201 is low, EGT and EGB will be pulled up to VEGSUOT and VEGSUPB, respectively. When the output of high voltage level shifter 1201 is high, EGT and EGB will be pulled to ground. EGT is applied to erase gate terminals (EGT) 26 of the cells in the row, and EGB is applied to erase gate terminals (EGB) 16 of the cells in the row.

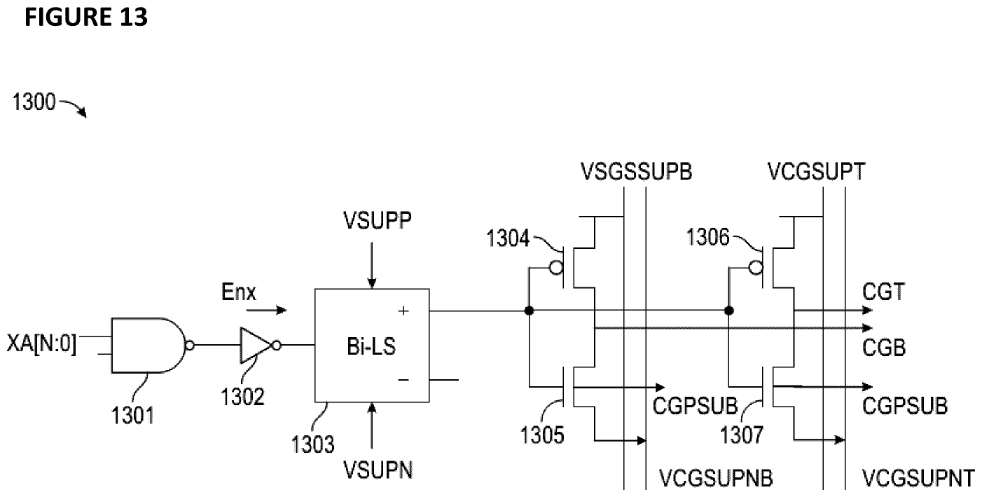

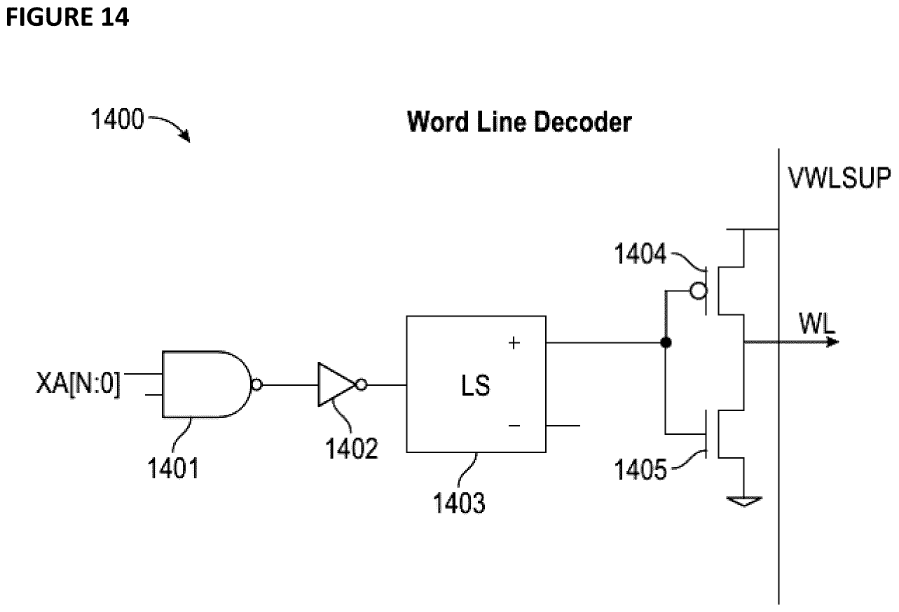

FIGS. 13 and 14 collectively depict a portion of a row decoder. Those circuits can be used with erase gate decoder 1100 from FIG. 11 or erase gate decoder 1200 from FIG. 12 to provide word line, control gate line, and erase gate line signals for a particular row. The same circuitry will be present for all other rows in a memory array.

FIG. 13 depicts a portion of control gate decoder CG 1300 associated with a single row in a memory array. CG decoder 1300 can provide positive voltage or negative voltage on the CG per one of the tables in FIGS. 4, 5, 6, and 7. It is to be understood that the same circuitry will be contained for all other rows in the memory array. A decoded row address, XA[N:0] comprising N+1 lines is received by NAND gate 1301. When the decoded row address corresponds to the row in question, the output of NAND gate will be 0 (meaning that the row is being selected); in all other instances, it will be 1 (meaning that the row is unselected). Inverter 1302 receives the output of NAND gate 1001 and inverts the signal, such that the output of inverter is 1 when the row is being selected and 0 when the row is unselected. The output of inverter 1302 is provided to bi-directional level shifter 1303 (meaning its positive supply can be positive or ground and its negative supply can be ground or negative voltage, which means its outputs can be positive or negative or ground), which inverts the signal and also outputs different voltages than the inputs for a high signal, a low signal, or both. The output of level shifter 1303 is applied to the gates of PMOS transistors 1304 and 1306 and NMOS transistors 1305 and 1307. When the row is selected, the output of level shifter 1303 will be low, which turns on PMOS transistors 1304 and 1306 and turns off NMOS transistors 1305 and 1307 and pulls up the outputs CGB and CGT to VCGSUPB and VCGSUPT, respectively. When the row is unselected, the output of level shifter 1303 will be high, which turns off PMOS transistors 1304 and 1306 and turns on NMOS transistors 1305 and 1307, which pulls down to VCGSUPNB or VCGSUPNT (e.g., ground, negative voltage) the outputs CGB and CGT. CGT is applied to control gate terminals (CGT) 24 of the cells in the row, and CGB is applied to control gate terminals (CGB) 14 of the cells in the row. The voltages on CGT or CGB are according to one of the tables in FIGS. 4, 5, 6, and 7.

FIG. 14 depicts a portion of word line decoder (with a level shifter for output) 1400 associated with a single row in a memory array. It is to be understood that the same circuitry will be contained for all other rows in the memory array. A row address, XA[N:0] comprising N+1 bits is received by NAND gate 1401. When the row address corresponds to the row in question, the output of NAND gate will be 0 (meaning that the row is being selected); in all other instances, it will be 1 (meaning that the row is unselected). Inverter 1402 receives the output of NAND gate 1401 and inverts the signal, such that the output of inverter is 1 when the row is being selected and 0 when the row is unselected. The output of inverter 1402 is provided to level shifter 1403, outputs different voltages than the inputs for a high signal, a low signal, or both. The output of level shifter 1403 is applied to the gates of PMOS transistor 1404 and NMOS transistor 1405. When the row is selected, the output of level shifter 1403 will be low, which turns on PMOS transistor 1404 and turns off NMOS transistor 1405 and pulls up the output WL to VWLSUP (which supply the voltage level per one of the tables in FIGS. 4, 5, 6, and 7). When the row is unselected, the output of level shifter 1403 will be high, which turns off PMOS transistor 1404 and turns on NMOS transistor 1405, which pulls down to ground the output WL. WL is applied to word line terminals (WL) 26 of the cells in the row.

The WL signal can be provided to erase gate decoders 1100 or 1200 in FIGS. 11 and 12. to generate the erase gate signals to be applied to the row.

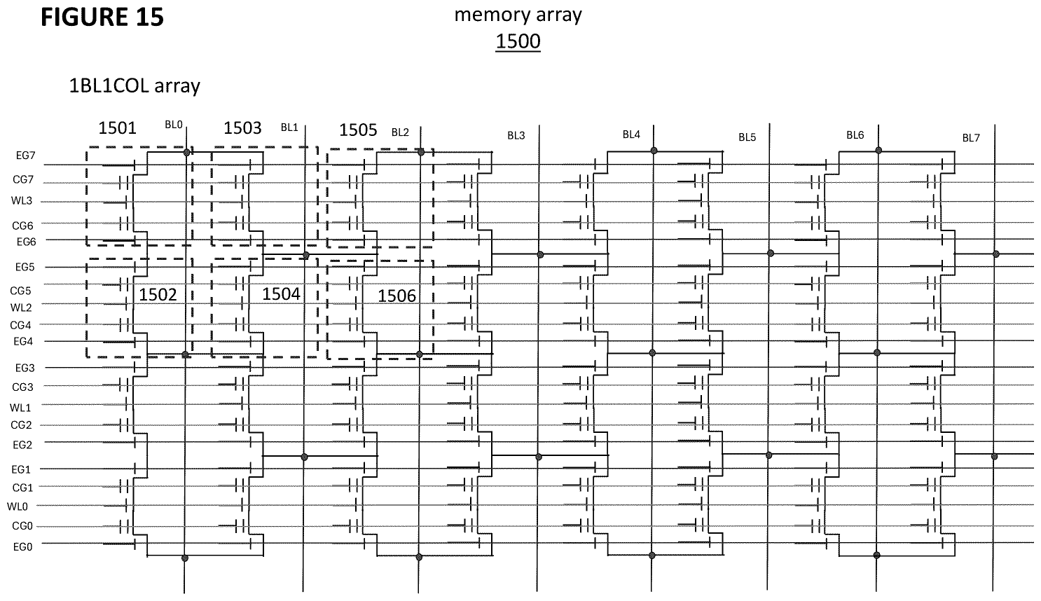

FIGS. 15-29 depict various memory array configurations where the memory comprises an array of memory cells of the design of memory cell 100 arranged into rows and columns.

FIG. 15 depicts memory array 1500, which comprises one bit line for each column of memory cells. Example memory cells 1501, 1502, 1503 1504, 1505, and 1506 are identified.

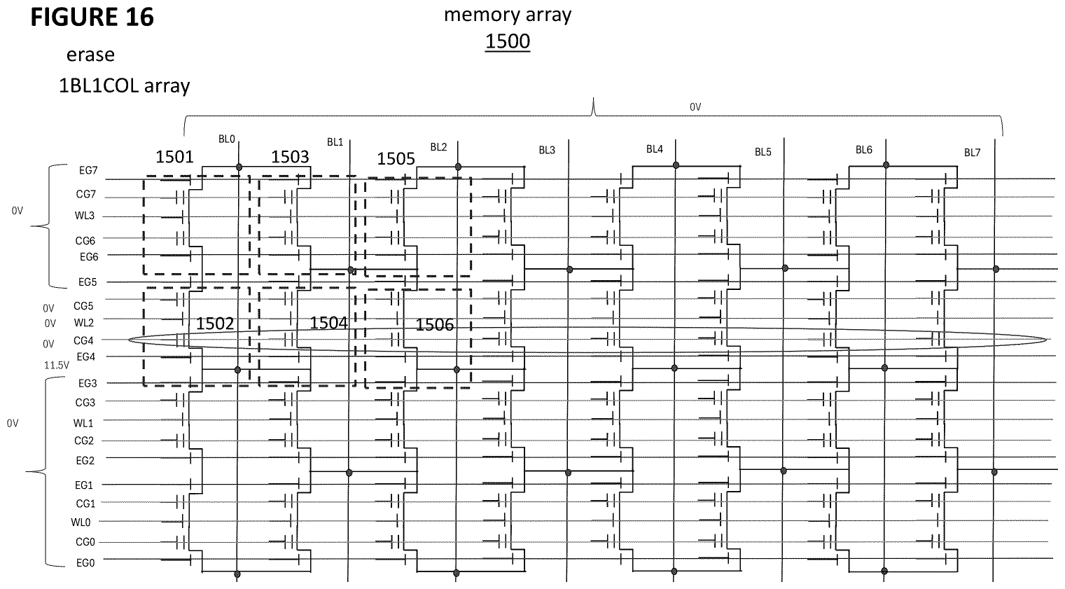

FIG. 16 depicts memory 1BL1COL array 1500 in erase operation from FIG. 15 with one BL interconnect (e.g., metal) shared between two BLTs and adjacent BL interconnect shared for two BLBs of memory cells. Example voltages are shown for the various rows and columns that can be applied to perform an erase operation of the second row of memory cells, including memory cells 1502, 1504, and 1506.

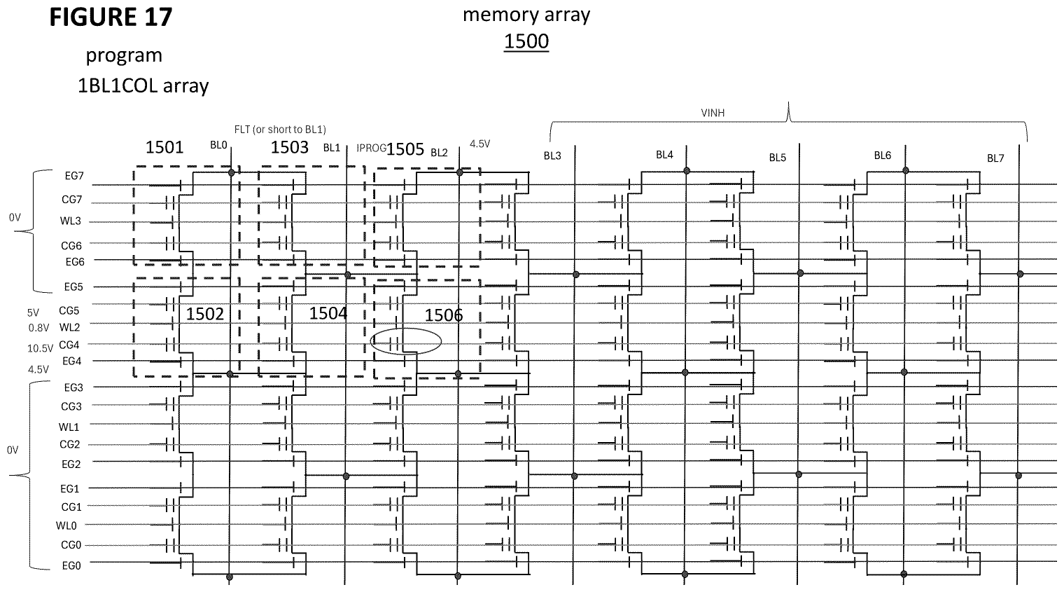

FIG. 17 depicts memory 1BL1COL array 1500 from FIG. 15 in program operation. Example voltages are shown for the various rows and columns that can be applied to perform a programming operation of a portion of memory cell 1506 in the second row and third column of memory array 1500. Selected memory 1506 is shown with bottom cell in program operation. Its bottom bitline is biased at a program voltage, e.g., 4.5V, the top bitline receives a program current with a resulting bias voltage Vdp on its bitline. Adjacent bitlines on the left of the bitline with program current will either float, be shorted to the right bitline, or receive a bias voltage Vdp. The bitlines to the right of the bitline that receives the program voltage (e.g., 4.5V) will be inhibited by an inhibit voltage V1NH.

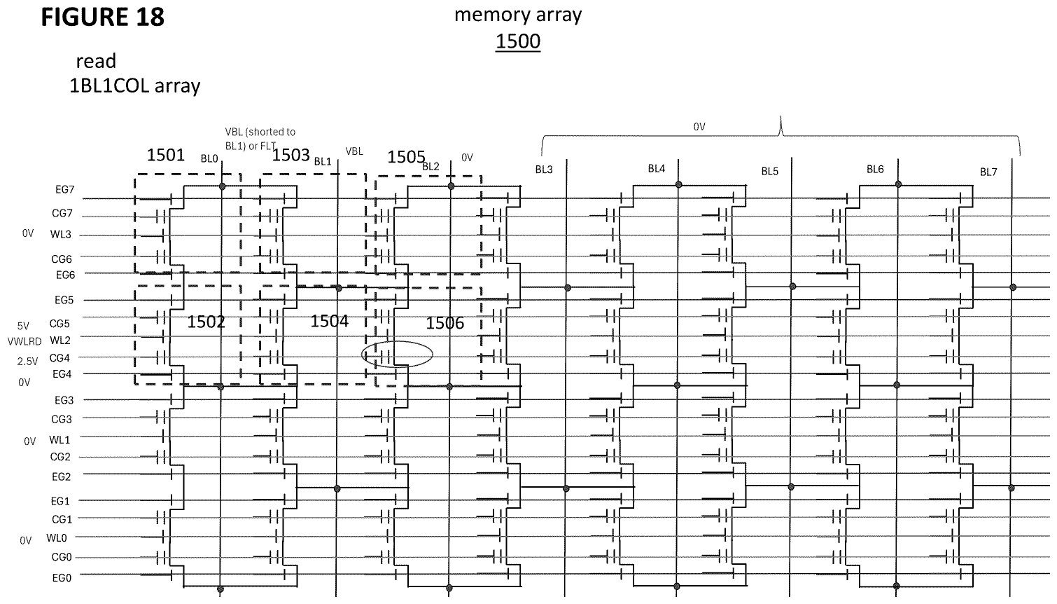

FIG. 18 depicts memory 1BL1COL array 1500 from FIG. 15. Example voltages are shown for the various rows and columns that can be applied to perform a read operation of a portion of a memory cell 1506 in the second row and third column of memory array 1500. Selected memory cell 1506 is shown with its bottom cell in read operation. Its bottom bitline is biased at 0V (gnd), and its top bitline receives a read bias voltage VBLRD (e.g., 0.6V) on its bitline. Adjacent bitlines on the left of the bitline that is biased VBLRD will either float, be shorted to the right bitline, or receive a bias voltage VBLRD. The bitlines to right of the bitline that receives read voltage VBLRD will be grounded by 0V (gnd).

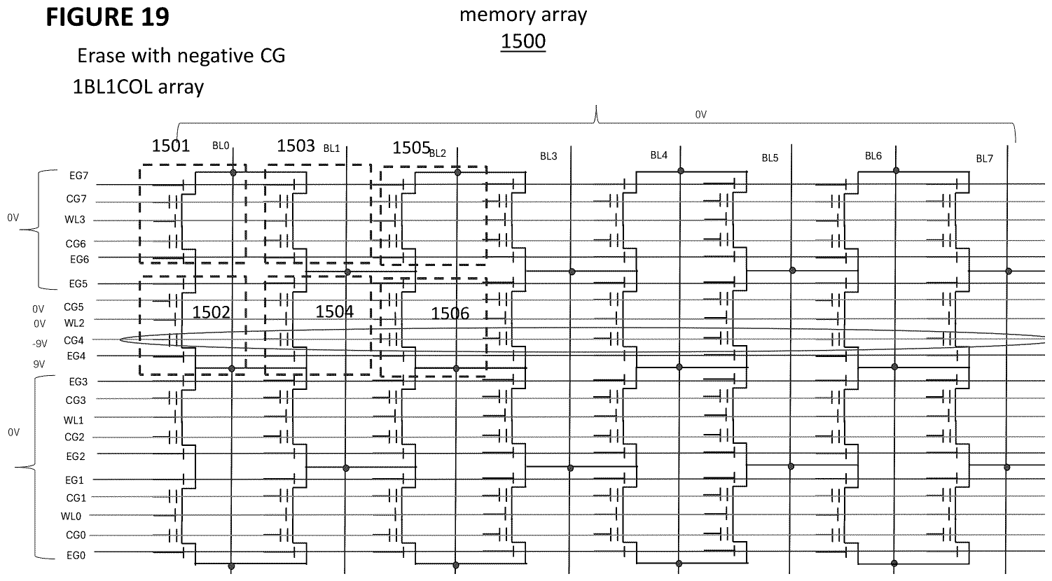

FIG. 19 depicts memory 1BL1COL array 1500 from FIG. 15. Example voltages are shown for the various rows and columns that can be applied to perform an erase operation of the second row of the array, including cells 1502, 1504, and 1506. The CG terminal voltage is negative while the EG terminal voltage is positive.

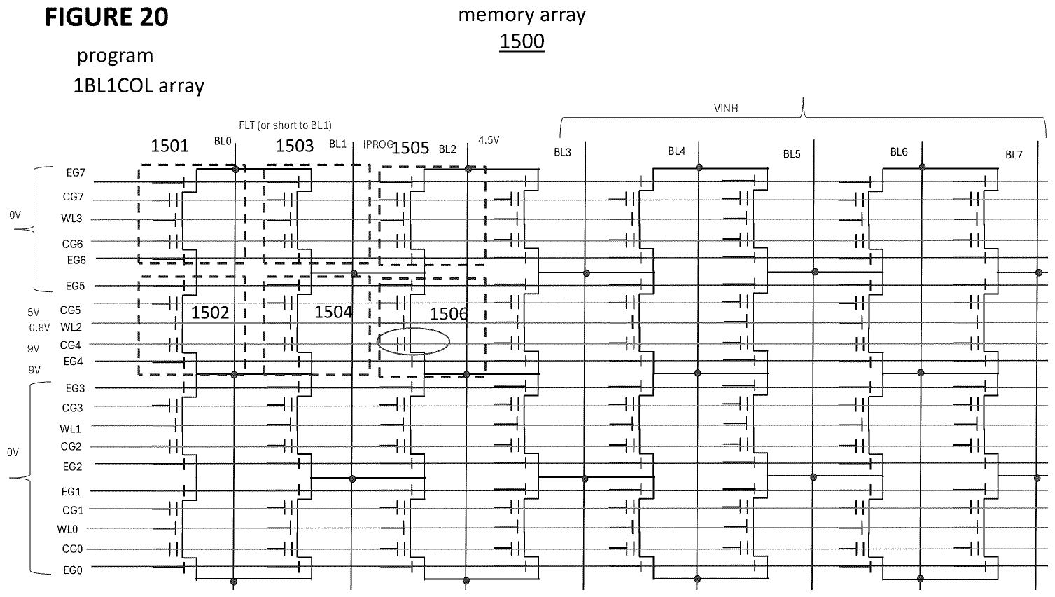

FIG. 20 depicts memory 1BL1COL array 1500 from FIG. 15. Example voltages are shown for the various rows and columns that can be applied to perform a programming operation of a portion of memory cell 1506 in the second row and third column of memory array 1500. The CG terminal receives a high voltage (e.g., 8-10V) while the EG terminal receives another high voltage (e.g., 8-10V). Other terminals receive voltages similar to FIG. 17.

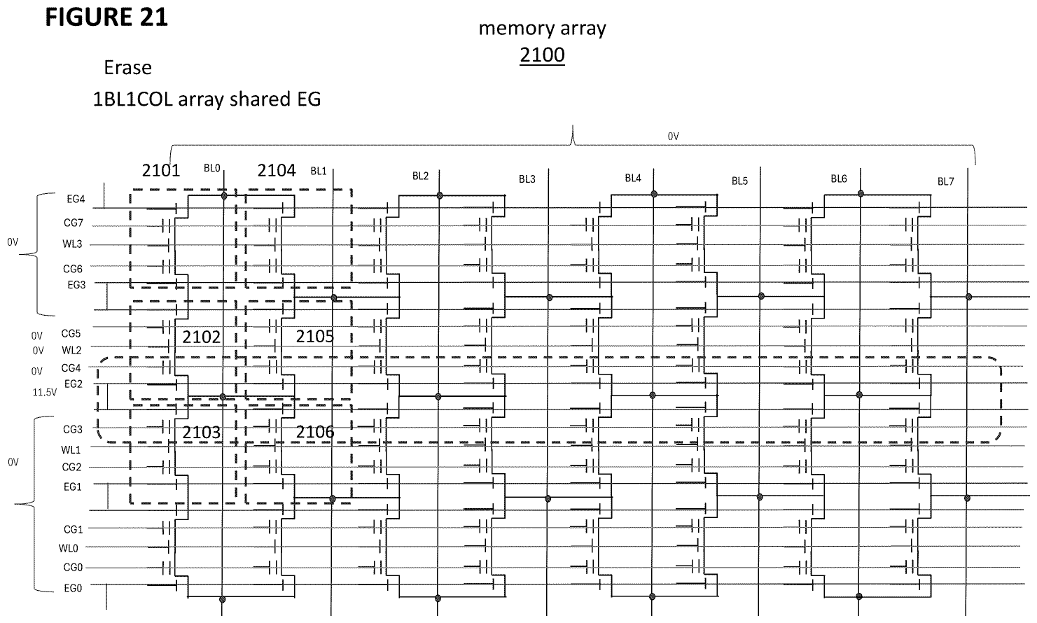

FIG. 21 depicts memory 1BL1COL array 2100 with shared EG, which comprises one bit line for each column of memory cells. Example memory cells 2101, 2102, 2103, 2104, 2105, and 2106 are identified. Memory cells 2101, 2103, 2104, and 2106 are top cells (with BLT, FGT, and CGT) and memory cells 2102 and 2105 are bottom cells (with BLB, FGB, and CGB). In memory array 2100, erase gate lines from bottom cells are coupled to erase gate lines for top cells in an adjacent row. For example, the erase gate line for the row containing cells 2102 and 2105 and the erase gate line for the row containing cells 2103 and 2106 are connected together as a single erase gate line, EG2. This allows the two rows to be erased in the same operation as sector comprising two rows of cells in memory array 2100.

In another example, more than two rows can share one EG line for all array described herein. This minimizes the size and complexity of the EG decoding circuitry.

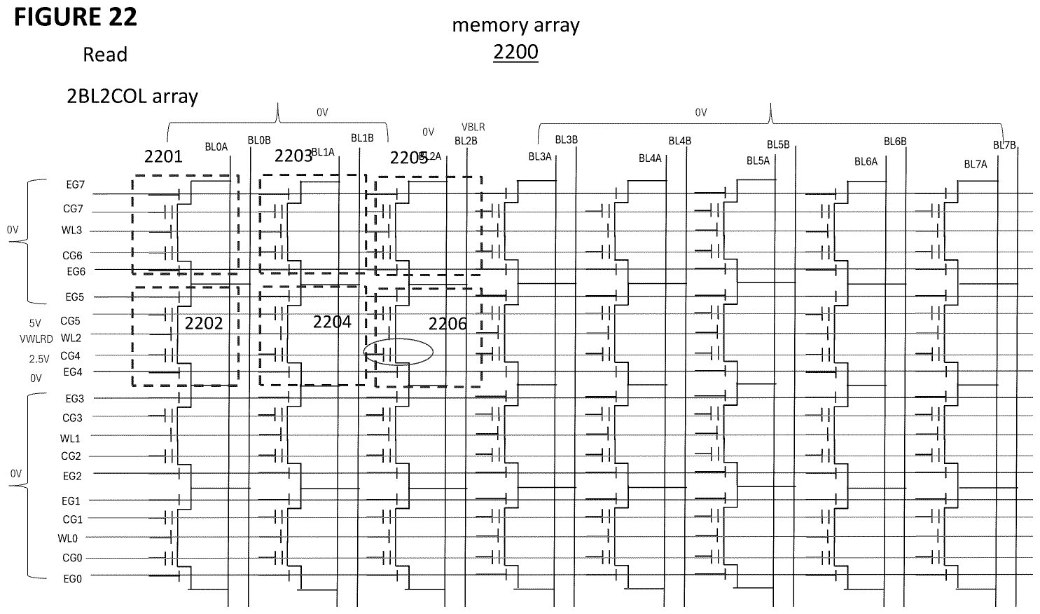

FIG. 22 depicts memory 2BL1COL array 2200, which comprises two bit lines for each column of memory cells. Example memory cells 2201, 2202, 2203 2204, 2205, and 2206 are identified. Example voltages are shown for the various rows and columns that can be applied to perform a read operation of a portion of memory cell 2206 in the second row and third column of memory array 2200. Selected bottom cell of memory unit 2206 is shown. The top bitline (connected to BLT) is biased at a read bias voltage VBLRD. Other bitlines are grounded. Conversely, if the top cell is selected for read, then the bottom BL (connected to BLB) is biased at read bias voltage VBLRD.

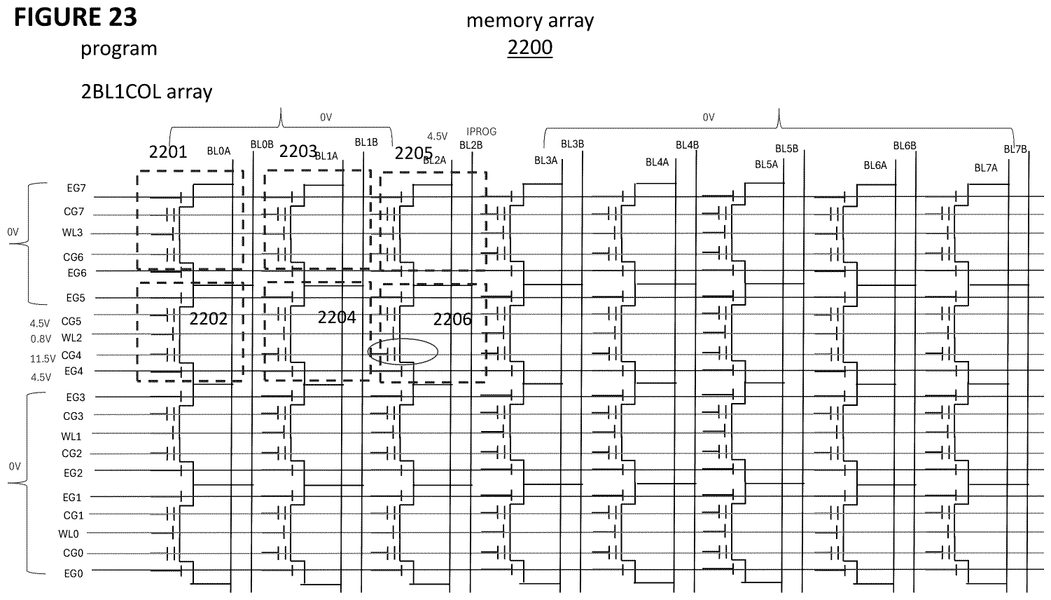

FIG. 23 depicts memory 2BL1COL array 2200 from FIG. 22. Example voltages are shown for the various rows and columns that can be applied to perform a program operation of a portion of memory cell 2206 in the second row and third column of memory array 2200. Selected bottom cell of memory unit 2206 is shown. The top bitline is biased at a program current IPROG. The bottom bitline (connected to BLB) is biased at a program voltage, e.g., 4.5V. Other unselected bitlines are grounded. Conversely, if the top cell is selected for read, then the bottom BL (connected to BLB) is biased at a program current IPROG and top bitline (connected to BLT) is biased at a program voltage, e.g., 4.5V. Alternatively, other unselected BLs can receive an inhibit voltage.

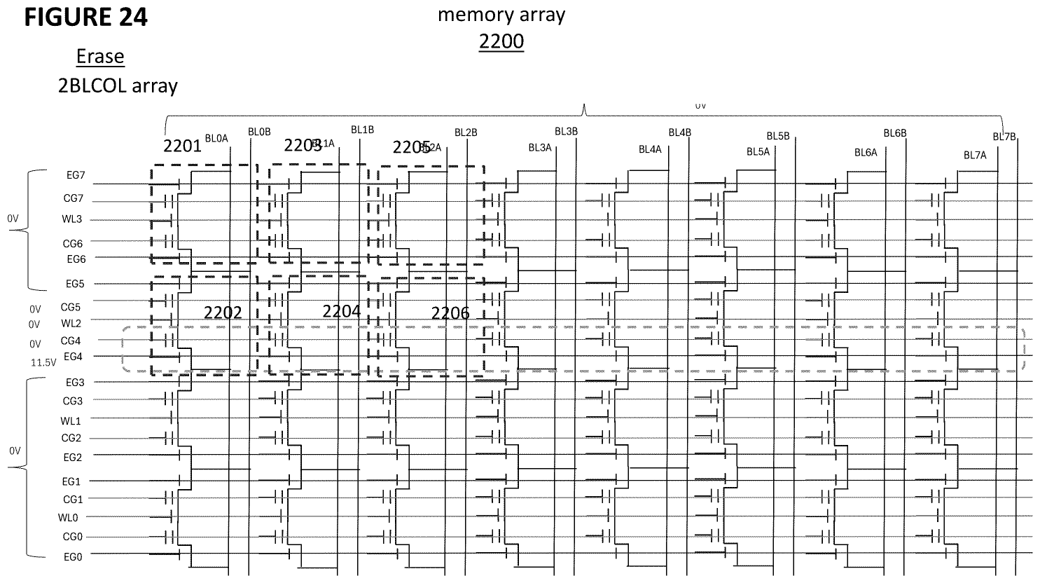

FIG. 24 depicts memory 2BL1COL array 2200 from FIG. 22. Example voltages are shown for the various rows and columns that can be applied to perform an erase operation of the second row of cells, including cells 2202, 2204, and 2206.

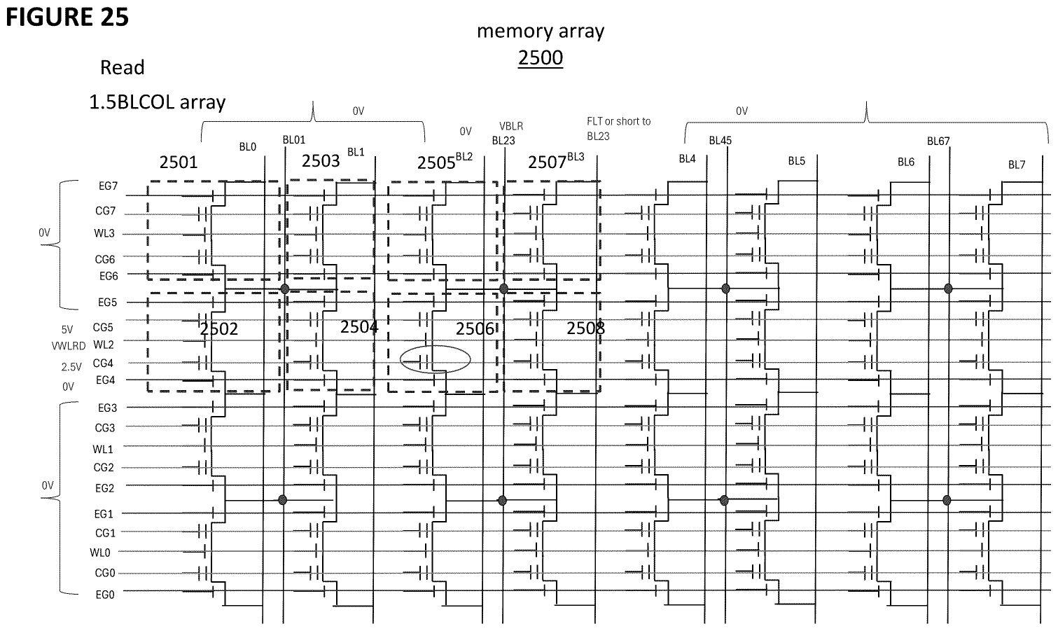

FIG. 25 depicts memory 1.5BL1COL array 2500, which comprises three bit lines for each two columns of memory cells. Example memory cells 2501, 2502, 2503 2504, 2505, 2506, 2507, and 2508 are identified. Memory cells 2501, 2503, 2505, and 2507 are top cells (with BLT, FGT, and CGT) and memory cells 2502, 2504, 2506, and 2508 are bottom cells (with BLB, FGB, and CGB). Example voltages are shown for the various rows and columns that can be applied to perform a read operation of a portion of memory cell 2508 in the second row and fourth column of memory array 2500. Selected bottom cell of memory cell unit 2506 is shown. Top BL (connected to BLT) is biased at as read bias voltage VBLRD and bottom BL (connected to BLB) is grounded. Adjacent BL to the selected BL receives a read bias VBLRD, floats, or is shorted to the selected BL itself. Other unselected BLs are grounded.

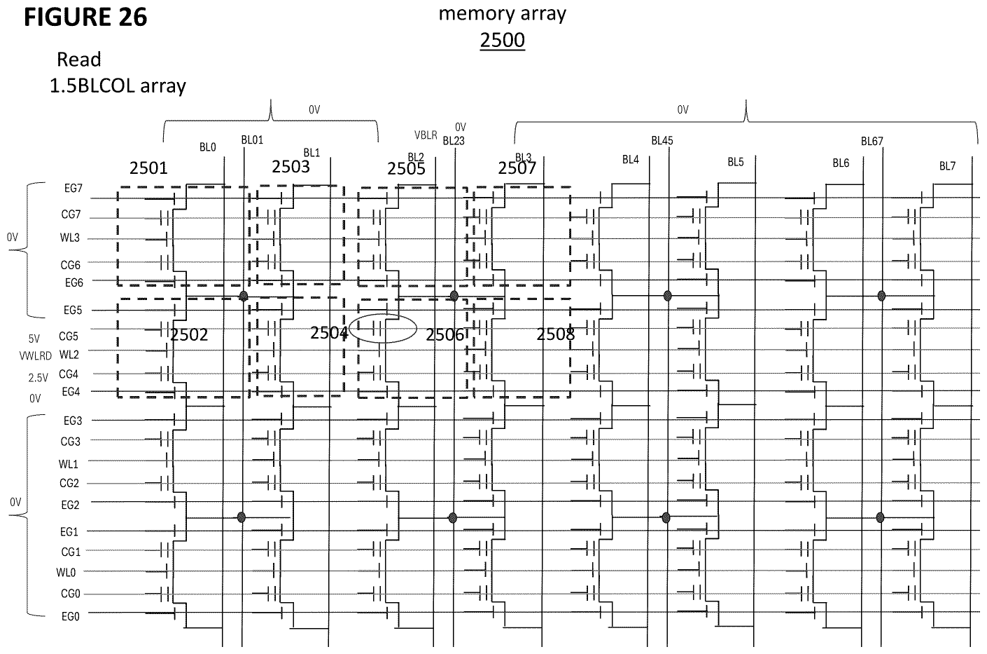

FIG. 26 depicts memory 1.5BL1COL array 2500 from FIG. 25. Example voltages are shown for the various rows and columns that can be applied to perform a read operation of a portion of memory cell 2506 in the second row and third column of memory array 2500. Selected top cell of memory cell unit 2506 is shown. Bottom BL (connected to BLB) is biased at read bias voltage VBLRD and top BL (connected to BLT) is grounded. Other unselected BLs are grounded.

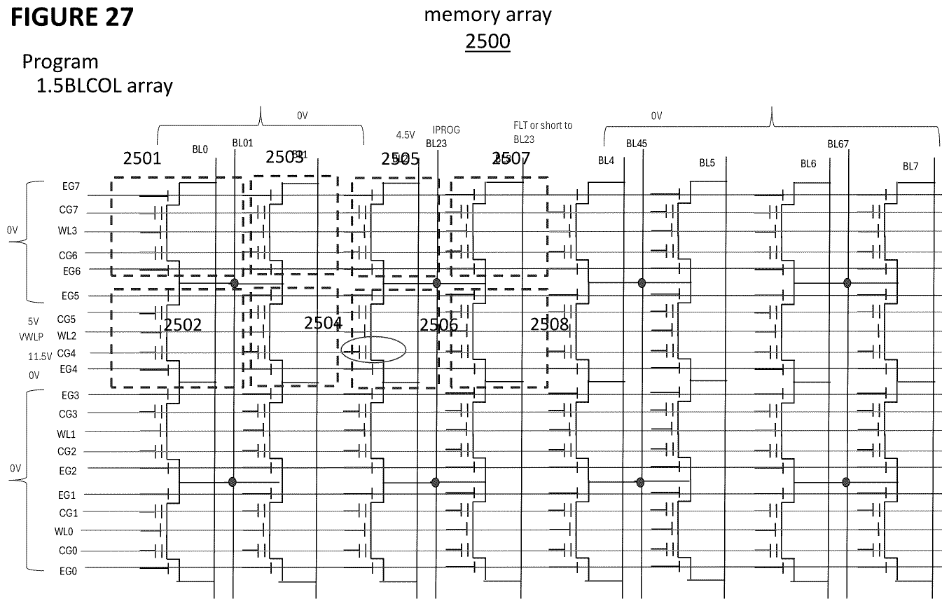

FIG. 27 depicts memory 1.5BL1COL array 2500 from FIG. 25. Example voltages are shown for the various rows and columns that can be applied to perform a program operation of a portion of memory cell 2508 in the second row and fourth column of memory array 2500. Selected bottom cell of memory cell unit 2506 is shown. Top BL (connected to BLT) is biased at program current IPROG and bottom BL (connected to BLB) is biased at a program voltage, e.g., 4.5V. Adjacent BL to the selected BL at IPROG either floats, is shorted to the selected BL itself, or receives a Vdp program BL voltage. Other unselected BLs are grounded.

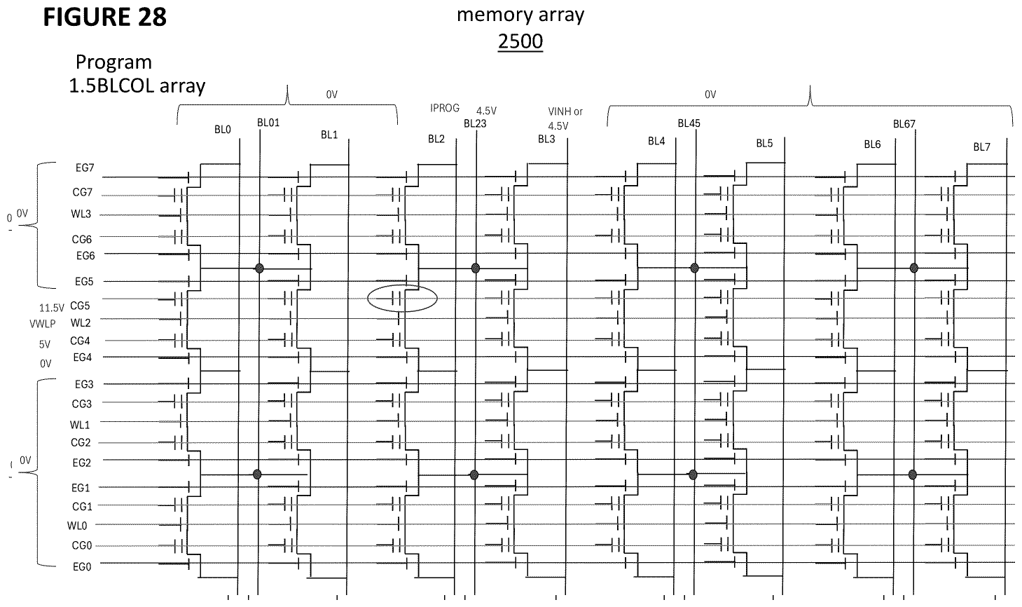

FIG. 28 depicts memory 1.5BL1COL array 2500 from FIG. 25. Example voltages are shown for the various rows and columns that can be applied to perform a program operation of a portion of memory cell 2508 in the second row and fourth column of memory array 2500. Selected top cell of memory cell unit 2506 is shown. Bottom BL (connected to BLB) is biased at a program current IPROG and top BL (connected to BLT) is biased at a program voltage, e.g., 4.5V. Other unselected BLs are grounded.

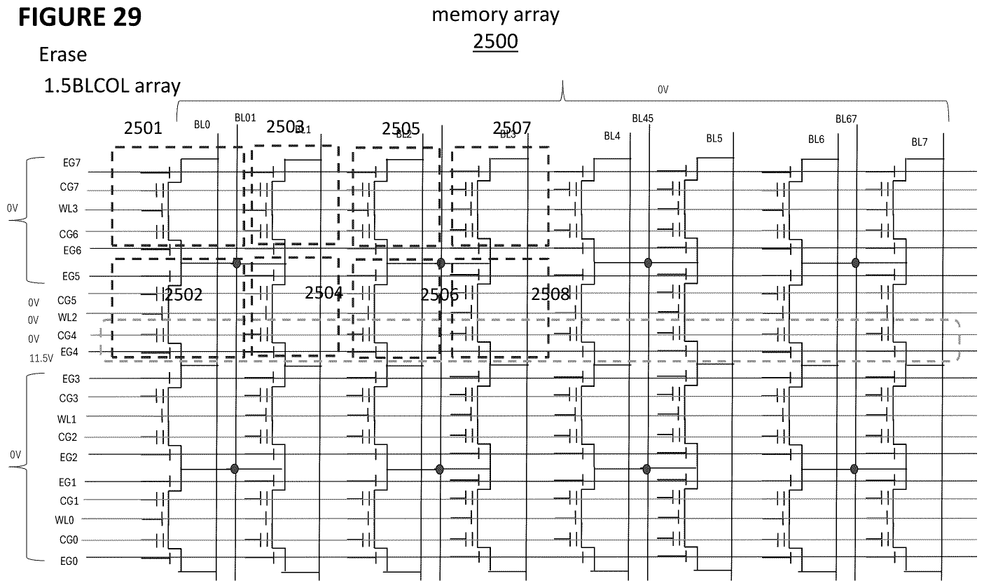

FIG. 29 depicts memory 1.5BL1COL array 2500 from FIG. 25. Example voltages are shown for the various rows and columns that can be applied to perform an erase operation of the second row of cells, including cells 2502, 2504, 2506, and 2508.

As used herein, the terms “over” and “on” both inclusively include “directly on” (no intermediate materials, elements or space disposed there between) and “indirectly on” (intermediate materials, elements or space disposed there between). Likewise, the term “adjacent” includes “directly adjacent” (no intermediate materials, elements or space disposed there between) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements there between, as well as forming the element indirectly on the substrate with one or more intermediate materials/elements there between.

What is claimed is:

1. A system comprising:
an array of non-volatile memory cells arranged into rows and columns, each non-volatile memory cell comprising a first bit line terminal, a first erase gate terminal, a first control gate terminal, a first floating gate, a word line, a second floating gate, a second control gate terminal, a second erase gate terminal, and a second bit line terminal, wherein the first floating gate can store a first digital or analog value and the second floating gate can store a second digital or analog value; and
a bit line decoder for a column to selectively provide a first voltage to the first bit line terminals of non-volatile memory cells in the column and a second voltage to the second bit line terminals of the non-volatile memory cells in the column.

2. The system of claim 1, wherein the bit line decoder comprises for each column a first pair of transistors coupled to the first bit line terminal and a second pair of transistors coupled to the second bit line terminal, the first pair comprising a first transistor coupled to a first voltage and a second transistor coupled to ground and the second pair comprising a third transistor coupled to a second voltage and a fourth transistor coupled to ground.

3. The system of claim 2, comprising a fifth transistor to selectively coupled the first bit line terminal and the second bit line terminal.

4. The system of claim 1, comprising:
a row decoder for a row to selectively provide a third voltage to word line terminals of non-volatile memory cells in the row, to selectively provide a fourth voltage to first control gate terminals of the non-volatile memory cells in the row, to selectively provide a fifth voltage to second control gate terminals of the non-volatile memory cells in the row, to selectively provide a sixth voltage to first erase gate terminals of the non-volatile memory cells in the row, and to selectively provide a seventh voltage to second erase gate terminals of the non-volatile memory cells in the row.

5. The system of claim 4, wherein the row decoder comprises a word line decoder to generate the third voltage.

6. The system of claim 4, wherein the row decoder comprises a control gate decoder to generate the fourth voltage and the fifth voltage.

7. The system of claim 4, wherein the row decoder comprises an erase gate decoder to generate the sixth voltage and the seventh voltage.

8. The system of claim 7, wherein one or more of the sixth voltage and the seventh voltage is a positive voltage.

9. The system of claim 7, wherein one of more of the fourth voltage and the fifth voltage is a negative voltage.

10. A system comprising:
an array of non-volatile memory cells arranged into rows and columns, each non-volatile memory cell comprising a first bit line terminal, a first erase gate terminal, a first control gate terminal, a first floating gate, a word line, a second floating gate, a second control gate terminal, a second erase gate terminal, and a second bit line terminal, wherein the first floating gate can store a first digital or analog value and the second floating gate can store a second digital or analog value;
wherein each column in the array contains a first bitline coupled to first bit line terminals of non-volatile memory cells in the column and a second bitline coupled to second bit line terminals of non-volatile memory cells in the column.

11. The system of claim 10, wherein erase gate terminals of a first row of memory cells is coupled to erase gate terminals for a second row of memory cells.

12. A system comprising:
an array of non-volatile memory cells arranged into rows and columns, each non-volatile memory cell comprising a first bit line terminal, a first erase gate terminal, a first control gate terminal, a first floating gate, a word line, a second floating gate, a second control gate terminal, a second erase gate terminal, and a second bit line terminal, wherein the first floating gate can store a first digital or analog value and the second floating gate can store a second digital or analog value;
wherein a pair of adjacent columns in the array contains a first bitline coupled to first bit line terminals of non-volatile memory cells in the first column, a second bitline coupled to first bit line terminals of non-volatile memory cells in the second column and a third bitline coupled to second bit line terminals of non-volatile memory cells in the first column and to second bit line terminals of non-volatile memory cells in the second column.

13. A system comprising:
an array of multi-value memory cells arranged into rows and columns, each multi-value memory cell comprising a first portion to store a first value and a second portion to store a second value;
wherein a pair of adjacent columns in the array comprise a first bitline coupled to multi-value memory cells in a first column, a second bitline coupled to multi-value cells in a second column, and a third bitline coupled to the multi-value memory cells in the first column and the multi-value memory cells in the second column; and
wherein when the second portion is to be read, a bit line adjacent to the second bitline is floated, shorted to the second bitline, or receives a bias voltage.

14. The system of claim 13,
wherein when the first portion is to be read, a bitline adjacent to the first bitline is floated or shorted to ground.

15. A system comprising:
an array of multi-value memory cells arranged into rows and columns, each multi-value memory cell comprising a first portion to store a first value and a second portion to store a second value;
wherein a pair of adjacent columns in the array comprise a first bitline coupled to multi-value memory cells in a first column, a second bitline coupled to multi-value cells in a second column, and a third bitline coupled to the multi-value memory cells in the first column and the multi-value memory cells in the second column; and
wherein when the first portion is to be read, a bit line adjacent to the first bit line is floated or shorted to ground.

16. A system comprising:
an array of multi-value memory cells arranged into rows and columns, each multi-value memory cell comprising a first portion to store a first value and a second portion to store a second value;
wherein a pair of adjacent columns in the array comprise a first bitline coupled to multi-value memory cells in a first column, a second bitline coupled to multi-value cells in a second column, and a third bitline coupled to the multi-value memory cells in the first column and the multi-value memory cells in the second column; and
wherein when the second portion is to be programmed, a bitline adjacent to the second bitline is floated, shorted to the second bitline, or receives a bias voltage.

17. The system of claim 16,
wherein when the first portion is to be programmed, a bit line adjacent to the first bit line is floated or shorted to ground.

18. A system comprising:
an array of multi-value memory cells arranged into rows and columns, each multi-value memory cell comprising a first portion to store a first value and a second portion to store a second value;
wherein a pair of adjacent columns in the array comprise a first bitline coupled to multi-value memory cells in a first column, a second bitline coupled to multi-value cells in a second column, and a third bitline coupled to the multi-value memory cells in the first column and the multi-value memory cells in the second column; and
wherein when the first portion is to be programmed, a bitline adjacent to the first bitline is floated or shorted to ground.

19. A bit line decoder comprising:
a plurality of sets of transistors, each of the plurality of sets of transistors connected to a bit line in a memory array and comprising a first transistor and a second transistor, wherein the second transistor is coupled to ground;
a first multiplexor for connecting a first signal to the first transistor in one of the plurality of sets of transistors in response to a first select signal;
a second multiplexor for connecting a second signal to the second transistor in one of the plurality of sets of transistors in response to a second select signal; and
a plurality of transistors, each of the plurality of transistors arranged between adjacent sets of transistors in the plurality of sets of transistors to short the adjacent sets of transistors in response to a control signal.

20. A circuit coupled to a row of a memory array, the circuit comprising:
an address decoder for outputting a row enable signal in response to an address;
a level shifter for generating an output, wherein the output is a first voltage when the row enable signal is asserted and ground when the row enable signal is not asserted;
a first inverter for outputting a first control gate signal in response to the output;
a second inverter for outputting a second control gate signal in response to the output; and
a third inverter for outputting a word line signal in response to the output.

21. The circuit of claim 20, comprising:
a high voltage level shifter to generate a second output in response to the word line signal and an enable signal;
a first erase circuit to output a first erase gate signal in response to the second output; and
a second erase circuit to output a second erase gate signal in response to the second output.

22. The circuit of claim 21, wherein the first erase circuit comprises:
a first PMOS transistor comprising a first terminal coupled to a first voltage source, a gate to receive the second output, and a second terminal;
a second PMOS transistor comprising a first terminal coupled to the second terminal of the first PMOS transistor, a gate to receive a first control signal, and a second terminal;
a first NMOS transistor comprising a first terminal coupled to the second terminal of the second PMOS transistor to provide the first erase gate signal, a gate to receive a second control signal, and a second terminal; and
a second NMOS transistor comprising a first terminal coupled to the second terminal of the first NMOS transistor, a gate to receive the second output, and a second terminal coupled to ground.

23. The circuit of claim 22, wherein the second erase circuit comprises:
a third PMOS transistor comprising a first terminal coupled to a second voltage source, a gate to receive the second output, and a second terminal;
a fourth PMOS transistor comprising a first terminal coupled to the second terminal of the third PMOS transistor, a gate to receive the first control signal, and a second terminal;
a third NMOS transistor comprising a first terminal coupled to the second terminal of the fourth PMOS transistor to provide the second erase gate signal, a gate to receive the second control signal, and a second terminal; and
a fourth NMOS transistor comprising a first terminal coupled to the second terminal of the third NMOS transistor, a gate to receive the second output, and a second terminal coupled to ground.

24. The circuit of claim 21, wherein the first erase circuit comprises:
a first PMOS transistor comprising a first terminal coupled to a first voltage source, a gate to receive the second output, and a second terminal; and
a first NMOS transistor comprising a first terminal coupled to the second terminal of the first PMOS transistor to provide the first erase gate signal, a gate to receive the second output, and a second terminal coupled to ground.

25. The circuit of claim 24, wherein the second erase circuit comprises:
a second PMOS transistor comprising a first terminal coupled to a second voltage source, a gate to receive the second output, and a second terminal; and
a second NMOS transistor comprising a first terminal coupled to the second terminal of the second PMOS transistor to provide the second erase gate signal, a gate to receive the second output, and a second terminal coupled to ground.

26. A circuit coupled to a row of a memory array, the circuit comprising:
an address decoder for outputting a row enable signal in response to an address;
a bi-directional level shifter for generating an output, wherein the output is a first voltage when the row enable signal is asserted and a second voltage when the row enable signal is not asserted, wherein the first voltage can be a positive voltage or ground and the second voltage can be a negative voltage or ground;
a first inverter for outputting a first control gate signal in response to the output; and
a second inverter for outputting a second control gate signal in response to the output.
